(19) United States
(12) Patent Application Publication
(10) Pub. No.: US 2026/0340465 A1
(43) Pub. Date: Oct. 29, 2026

(54) MULTI-THROW SWITCHES-BASED CONTROL ARCHITECTURE FOR SUPERCONDUCTING QUBITS

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/045,518

(22) Filed: Feb. 4, 2025

(51) Int. Cl. G06N 10/40; G06N 10/70; H10N 70/20; H10N 79/00

(52) U.S. Cl. CPC G06N 10/40; G06N 10/70; H10N 70/231; H10N 79/00

(57) ABSTRACT

The technology described herein is generally directed towards using controlled multi-throw switches and signal splitters in a cryogenic microwave signal routing system and architecture. The multi-throw switches and signal splitters are controlled in a multiplexed fashion to manage analog waveform delivery to qubits under the control of classical logic. Similarly, multiplexed qubit readout is facilitated using multi-throw switch control. The multiplexed signal delivery to qubits, by controlling switch selection, signal splitter selection, and their states, results in high-fidelity qubit control in large qubit arrays. Qubit readout can be accomplished via switch selection and switch state control, facilitating multiplexed signal readout from any selected qubit. Further, the system/architecture allows for obtaining telemetry data from individual qubits using the multi-throw switches, so that the system can adjust for variations in qubit parameters, ensuring optimal performance, while providing real-time feedback for calibration and error detection.

### BACKGROUND

As quantum computing systems transition from experimental few-qubit quantum systems to large-scale quantum processors, larger quantum computing systems call for different control architectures and supporting devices. For example, as quantum processors grow substantially with respect to the number of qubits therein, signal routing and readout systems become significant design considerations.

### BRIEF DESCRIPTION OF THE DRAWINGS

The technology described herein is illustrated by way of example and not limited to the accompanying figures in which like reference numerals indicate similar elements and in which:

FIG. 1 is a representation of example multi-throw switches integrated into an example qubit control and addressing architecture, in accordance with various embodiments and implementations of the subject disclosure.

FIG. 2 is a representation of an example multi-throw switch and a symbolic representation thereof for use with the example architecture of FIG. 1, in accordance with various embodiments and implementations of the subject disclosure.

FIG. 3 is a block diagram representation of an example qubit control and addressing architecture that includes a multi-throw switch array, in accordance with various embodiments and implementations of the subject disclosure.

FIGS. 4A and 4B show an example timing sequence (FIG. 4A) of single-qubit gate operations on two gates, with a corresponding hardware architecture responsible for routing signals to selected qubits (FIG. 4A), in accordance with various embodiments and implementations of the subject disclosure.

FIGS. 5A and 5B show an example timing sequence (FIG. 5A) of two-qubit gate operations on two different gates (relative to FIGS. 4A and 4B), with a corresponding hardware architecture responsible for routing signals to selected qubits (FIG. 5A), in accordance with various embodiments and implementations of the subject disclosure.

FIGS. 6A and 6B show an example timing sequence (FIG. 6A) of two-qubit gate operations on two different gates (relative to FIGS. 4A, 4B 5A and 5B), with a corresponding hardware architecture responsible for routing signals to selected qubits (FIG. 6A), in accordance with various embodiments and implementations of the subject disclosure.

FIGS. 7A and 7B show an example timing sequence (FIG. 7A) of a readout operation on a qubit, and routing the readout information to a classical control system (FIG. 7B), in accordance with various embodiments and implementations of the subject disclosure.

FIG. 8 shows example time sequenced signal routing for qubit control using a splitter and multi-throw switches, showing paths at different time points corresponding to FIG. 4A-7B, in accordance with various embodiments and implementations of the subject disclosure.

FIG. 9A is a representation of one example type switch, suitable for use in the architecture and switches of FIG. 1-8, based on reversible switching of phase change material alloy between amorphous (high resistance) and a crystalline (low resistance) state using different electrical pulses, in accordance with various example embodiments and implementations of the subject disclosure.

FIG. 9B is a representation of a circuit model of an example phase change switch (PCS), in which switch activation is via voltage difference applied across an embedded resistive micro heater, along with an example layout of a phase change microwave switch and a zoomed-in section of a switch junction highlighting various design dimensions, in accordance with various example embodiments and implementations of the subject disclosure.

FIG. 10 is a flow diagram showing example operations related to addressing a selected qubit based on selecting states of multi-throw switches and signal splitters, in accordance with various aspects and implementations of the subject disclosure.

### DETAILED DESCRIPTION

Various implementations and embodiments of the technology described herein are generally directed towards a cryogenic microwave signal routing system and architecture using multi-throw switches and signal splitters. These elements manage analog waveform delivery and readout for qubits under the control of classical logic. By leveraging signal splitting and efficient routing, the technology provides high-fidelity control and facilitates readout of large qubit arrays.

In general, the system and architecture is based on multiplexed signal delivery to qubits, by controlling switch selection, signal splitter selection, and their states. Further, qubit readout can be accomplished via switch selection and switch state control, facilitating multiplexed signal readout from selected qubits.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

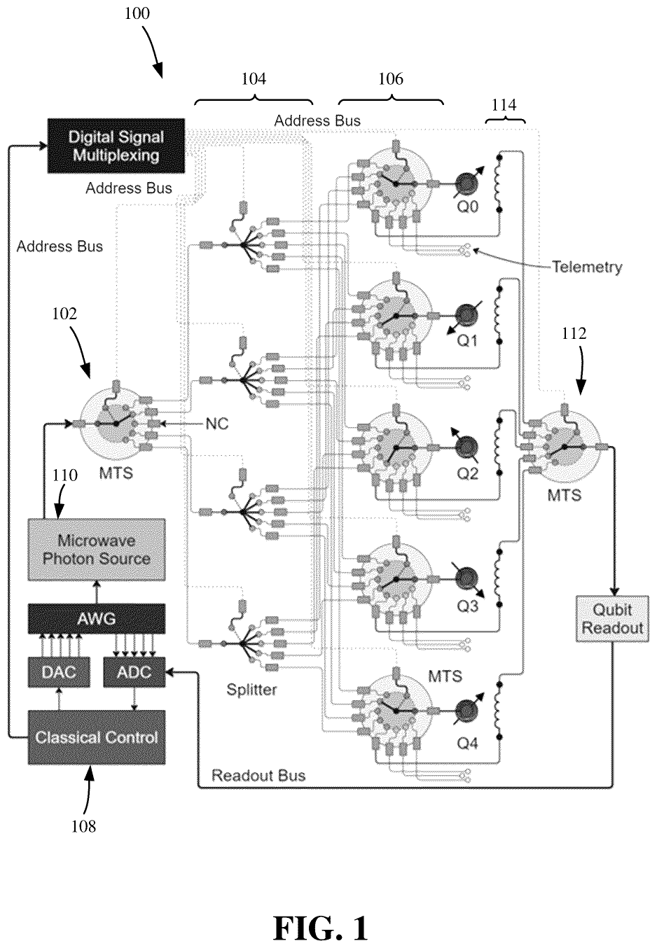

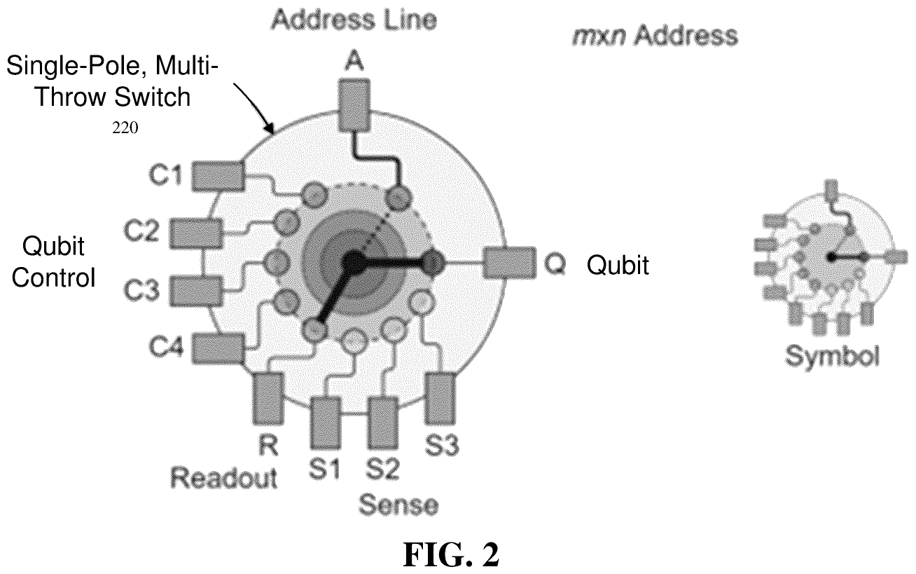

FIG. 1 shows an example architecture/system 100 for a cryogenic microwave signal routing with selective, multiplexed signal delivery to qubits, and switch-based selective readout of quantum state information from the qubits. The architecture features a cryogenic multi-throw switch (102) coupled to a group of microwave signal splitters (collectively labeled 104), which in turn are coupled to a group of cryogenic multi-throw switches (collectively labeled 106). Together, the switches 102 and 106, along with the splitters 104, route analog waveforms (microwave signals) to selected qubits (e.g., Q0-Q4 at 20 mK) under classical control (block 108). FIG. 2 shows contacts of a multi-pole, single-throw switch 220 suitable for use as (one of) the multi-throw switches 104.

The classical control (block 108) can be a high-performance cluster or server computing device, coupled for data output to the rest of the system via a digital-to-analog converter (DAC), and for input from the system via an analog-to-digital converter (ADC). One example output from the classical control (block 108) is to the arbitrary waveform generator (AWG) which provides the waveform to a microwave photon source 110 for outputting a microwave signal, via selected and controlled switches and splitters, to a selected qubit.

Also shown in FIG. 1 is a multi-pole, single-throw switch 112 coupled to inductors/resonators (collectively labeled 114) that are configured to read the qubits. Depending on the controlled states of the switches 106 and 112, any qubit can be a selected qubit, coupled to its associated (proximate) inductor/resonator, for readout of quantum state information therefrom. Qubit readout/quantum state information is obtained by the classical control device 108 via the ADC. Note that amplifiers and the like are generally used for readout of the relatively weak qubit information.

To summarize thus far, the system/architecture of FIG. 1 addresses the limitations of current quantum control systems by introducing a cryogenic microwave signal routing solution with multiplexed signal delivery to qubits. The system/architecture reduces the reliance on individual microwave photon sources for each qubit as in current quantum systems, instead enabling a shared set of waveform generators and converters to control multiple qubits. This both reduces hardware requirements and simplifies control.

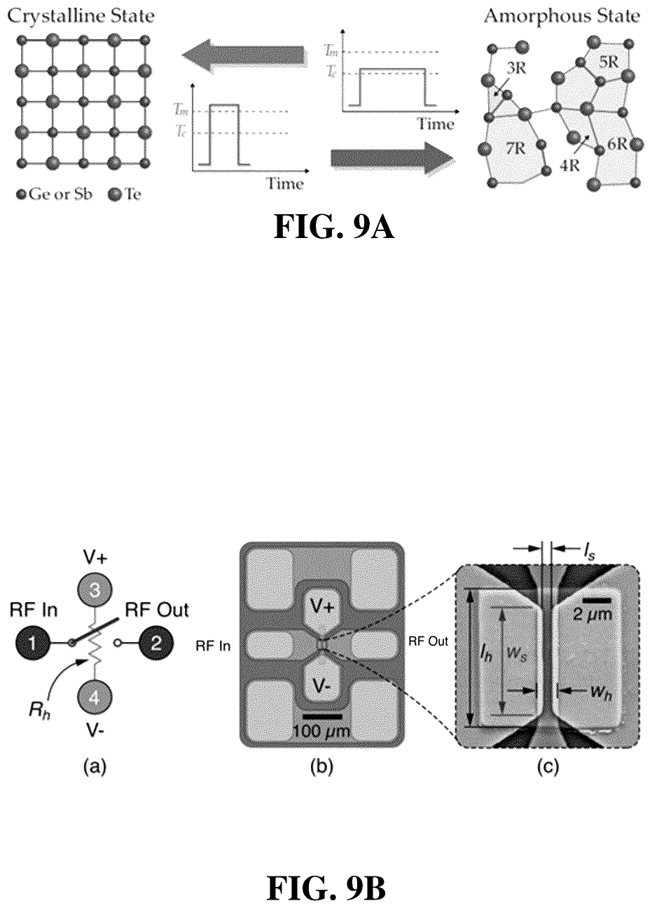

The benefits of the system 100 are obtained from the multi-throw switches, which route the microwave signals to selected qubits based on digital addressing. The multi-throw switches, which can use phase-change materials (FIGS. 9A and 9B), is highly suitable for cryogenic operation, facilitating precise control over the amplitude and phase of the microwave signals directed to each qubit. Control of the multi-throw switches facilitates selective routing of microwave signals between different paths, enabling the connection of one input to multiple outputs in a controlled manner. The digital addressing lines used for selecting and controlling the switch states of the qubits are separate from the high-bandwidth analog control signals.

Further, the system/architecture allows fetching telemetry data from individual qubits using multi-throw switches, so that the system can adjust for variations in qubit parameters, ensuring optimal performance. This also provides real-time feedback for calibration and error detection.

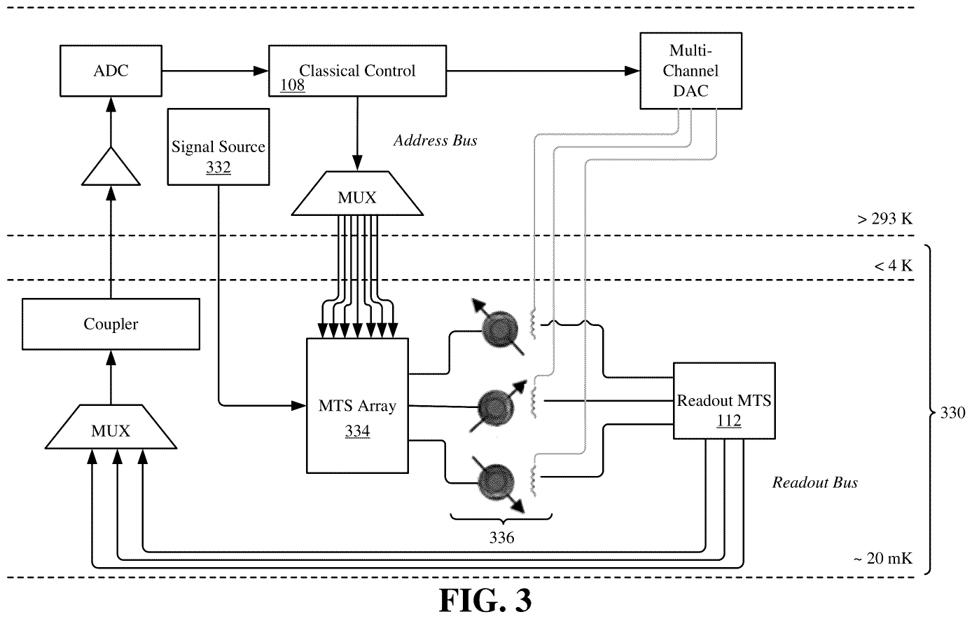

Given the large number of qubits and fast control requirements, parts of the control architecture are strategically placed at cryogenic temperatures, either on-chip or in close proximity thereto, using multichip modules and compact transmission lines. To balance the interconnect density, signal latency, and heat dissipation, the architecture is distributed across different temperature stages in a dilution refrigerator 330 as shown in FIG. 3. The signal source 332 generates microwave pulses, which are routed through an array 334 of multi-throw switches (MTS) to selectively target specific qubits 336 for quantum gate operations. The MTS array 334 is positioned near the qubits, as this minimizes the latency and synchronization issues that arise when signal travels over distances comparable to the wavelength of the control signals. The address bus, controlled by classical electronics at room temperature (around 293 K) determines which qubits are addressed. The readout process is conducted through a separate readout multi-throw switch 112, and the output is sent by the readout bus to the ADC for conversion into digital signals, to the classical control system 108.

In general, the system operates by breaking down quantum algorithms into sequences of universal quantum gates, using repeated single-and two-qubit operations. At the physical qubit level, these gate operations are executed through calibrated microwave waveforms applied to specific qubits or pairs of qubits during each clock cycle, as determined by the quantum program (e.g., algorithm) that is running. The quantum program is executed by the digital address bus, selecting qubits and qubit pairs to receive the appropriate waveform at the correct clock cycle. Similarly, qubit readout is performed by selecting specific qubits through the digital bus, in which the qubits are connected to multiplexing devices and analog readout circuitry.

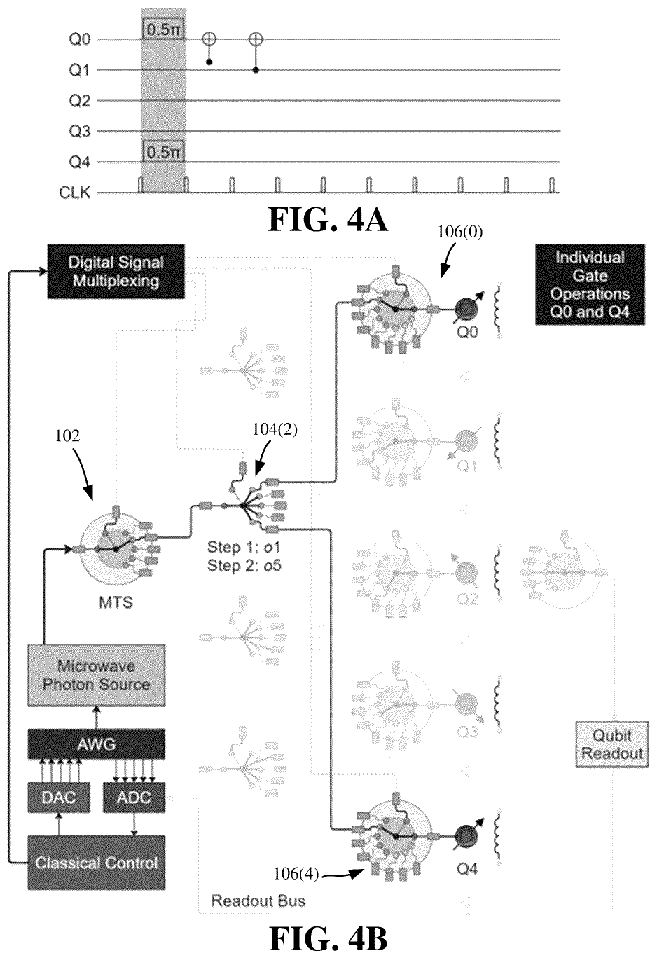

Examples of such quantum operations are shown in FIG. 4A-7B. more particularly, FIG. 4A shows the timing diagram of the gate operations applied to Q0 and Q4. FIG. 4B shows the hardware implementation of the same operations. More particularly FIG. 4A shows the timing sequence of single-qubit gate operations on Q0 and Q4 in the shaded region. The switch states and signal splitter states, as controlled by the computing device setting the various switch control inputs (switch address lines) and splitter control inputs (splitter address lines) via digital signal multiplexing is responsible for routing signals to selected qubits, ensuring efficient execution of quantum gates with minimal hardware resources. For example, in FIG. 4B, the multi-throw switch 102 is controlled to couple the microwave signal from its pole contact to the throw contact coupled to the microwave signal splitter 104(2). In turn, the microwave signal splitter 104(2) is controlled via its splitter control input to couple one of its splitter output contacts to the switch throw of the multi-throw switch 106(0), which is controlled to couple that throw to its pole contact coupled to the qubit Q0, and another splitter output contacts to the switch throw of the multi-throw switch 106(4), which is controlled to couple its throw to its pole contact coupled to the qubit Q4.

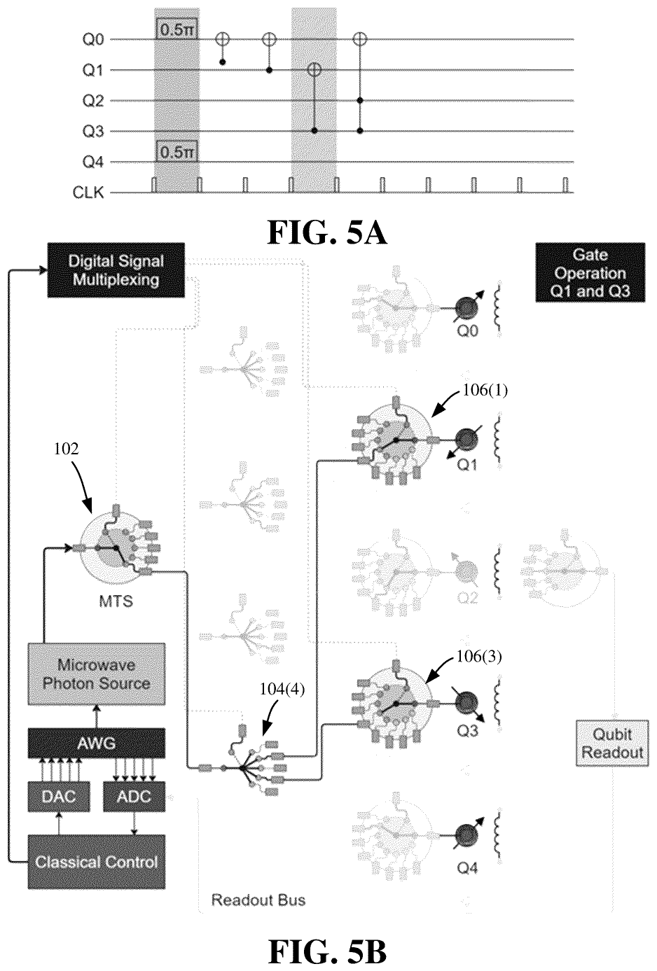

FIG. 5A shows the timing sequence of two-qubit gate operations on Q1 and Q3 (highlighted in the more centrally shaded region, that is, to the right of the region highlighted in FIG. 4A). FIG. 5B shows the various switch and splitter connections/switch states of multi-throw switches 102, 106(1) and 106(3), and signal splitter 104(4), for routing the signals to Q1 and Q3.

FIG. 5A shows the timing sequence of two-qubit gate operations on Q1 and Q3 (highlighted in the more centrally shaded region, that is, to the right of the region highlighted in FIG. 4A). FIG. 5B shows the various switch and splitter connections/switch states of multi-throw switches 102, 106(1) and 106(3), and signal splitter 104(4), for routing the signals to Q1 and Q3.

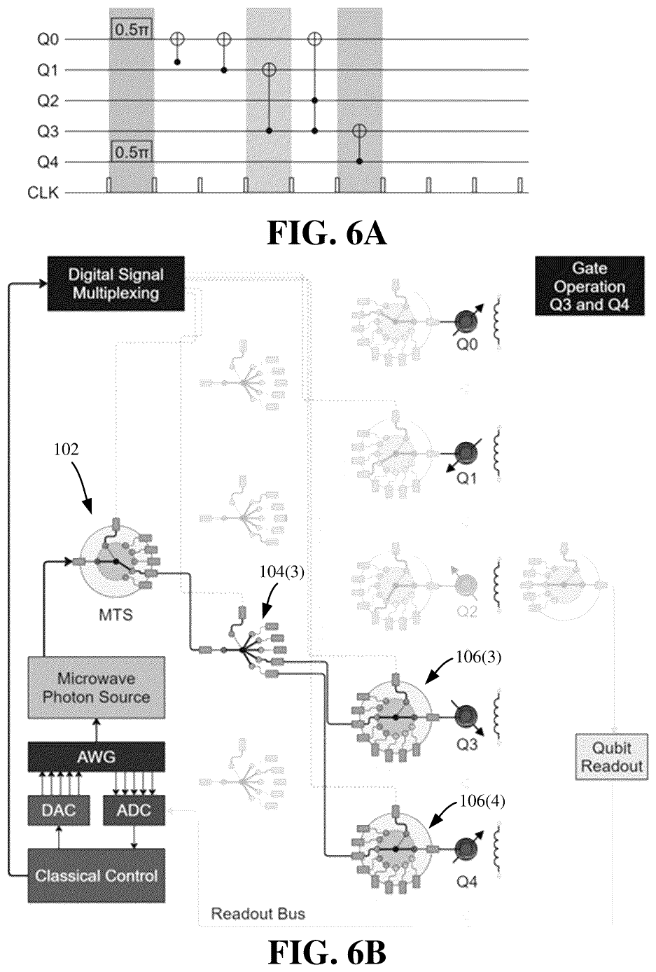

FIG. 6A shows the timing sequence of two-qubit gate operations on Q3 and Q4 (highlighted in the third shaded region from the left). FIG. 6B shows the various switch and splitter connections/switch states of multi-throw switches 102, 106(3) and 106(4), and signal splitter 104(3), for routing the signals to Q3 and Q4. As can be seen via FIG. 4A-6B, a microwave signal can be routed to any selected qubit or qubits by determining which switches and splitters are addressed, and controlling the switch/splitter states to couple the correct input and output contacts to one another.

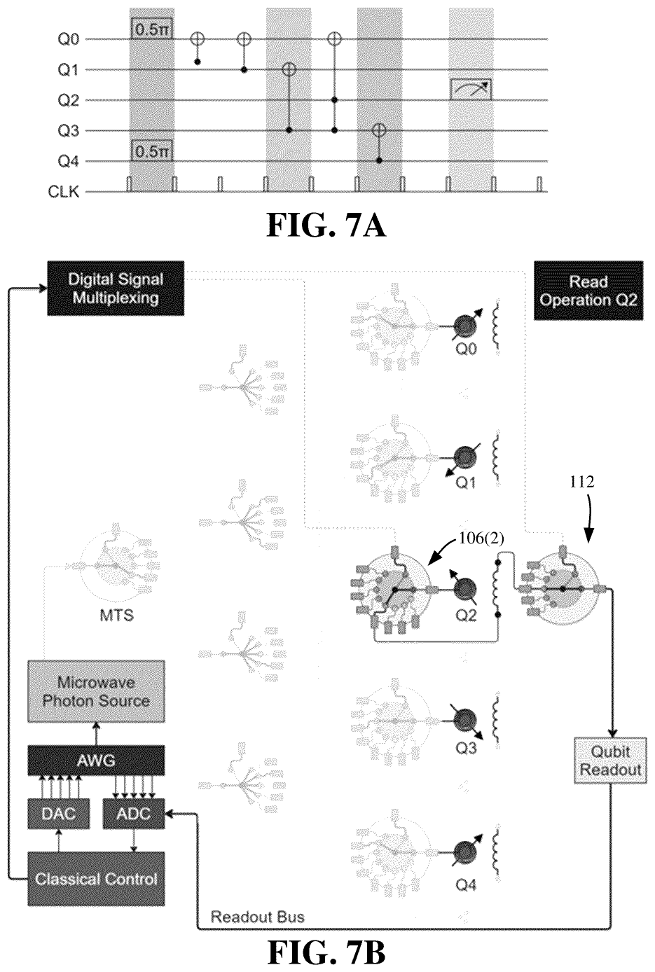

With respect to readout from the qubits, FIG. 7A shows the timing sequence of a readout operation on the qubit Q2 (highlighted in the rightmost shaded region). FIG. 7B shows the hardware architecture responsible for reading out signal from selected qubit Q2, then routing it to classical control after performing analog-to-digital signal conversion. As can be seen, the switch 106(2) and the switch 112 are controlled to couple the qubit Q 2/its associated inductor/resonator to the classical computer via the ADC.

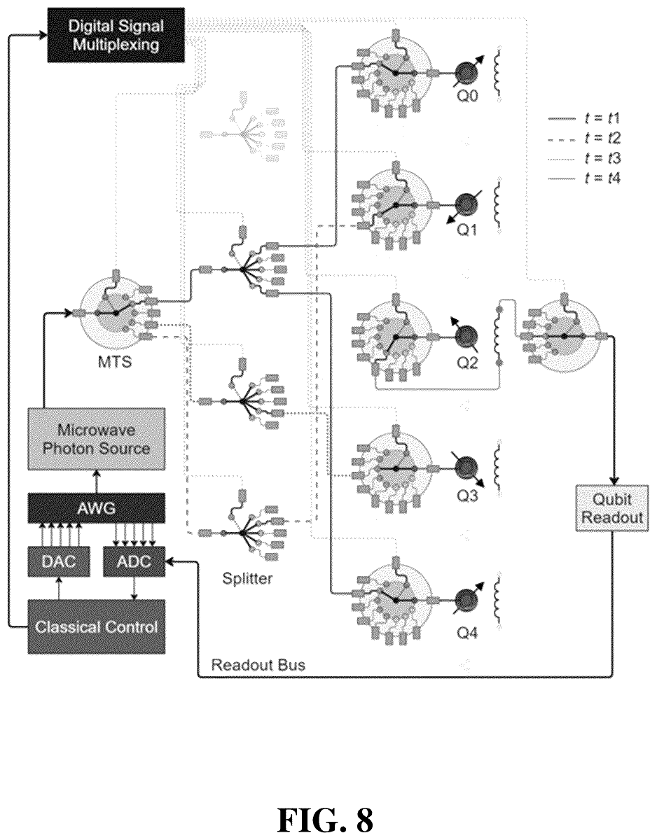

FIG. 8 summarizes the time-sequenced signal routing for qubit control using splitter and multi-throw switches. The different dash-type lines/line shading of the four paths represent the different time points (t1, t2, t3, and t4) in the signal routing cycle of FIGS. 4A-7B. At each time instance t1, t2, t3, the MTS directs microwave waveforms from a shared source to selected qubits, reducing the need for dedicated control lines, and at time instance t4, the MTS switches are controlled/configured to perform the readout of the qubit Q2.

Although the technology described herein is not limited to any type of switch, other than switch types with suitable switching speed and cryogenic usage properties, as mentioned, one suitable type of switch for cryogenic usage is based on phase change materials (PCMs). Phase change materials, which are used in phase change switches, are typically alloys of germanium (Ge), antimony (Sb), and/or tellurium (Te), and have the property to reversibly switch between amorphous and crystalline states (as shown in FIG. 9A) when subjected to controlled electrical heating, which alters their electrical resistance. The name ‘phase change’ is based on a phase change switch's ability to switch between two states, and the controllability allows controlled electrical coupling or decoupling of components coupled to the switch contacts.

As shown in FIG. 9A, a medium-amplitude, long-duration SET electrical energy (voltage or current) pulse is used to crystallize the material (turning the switch ON), while a short-duration, high-amplitude RESET pulse is used to amorphize the material (turning the switch OFF). The specific amplitude and duration of the SET and RESET pulses depend on the alloy composition of the phase change material. When the phase change material is in its disordered amorphous state (short-range atomic order), the material has a relatively high resistance due to electron scattering, impeding current flow. In contrast, the crystalline state (long-range atomic order) has a low resistance, enabling relatively high conductivity. This significant resistance difference is what allows phase change material devices to operate as switches.

Moreover, a phase change material device, shown in FIG. 9B, can latch into either state (ON or OFF) without requiring continuous power, making them energy-efficient and suitable for cryogenic environments where power dissipation is a significant consideration. This non-volatile behavior significantly enhances system scalability and efficiency in cryogenic environments. Indeed, at cryogenic temperatures, a phase change material's behavior remains intact, making a phase change material switch a suitable option for quantum computing systems. In the circuit model of a phase change switch shown in the left portion of FIG. 9B, switch activation or deactivation occurs by a voltage difference (pulse) applied across an embedded resistive micro heater Rₕ. The center and right portions of FIG. 9B shows an example layout of a phase change microwave switch; the zoomed-in portion on the right the switch junction highlights various example design dimensions.

One or more example implementations can be embodied in a system. The system can include a first multi-throw switch comprising a first pole coupled to a microwave photon source, respective first throws coupled to respective splitter input ports of respective splitters, and a first control input coupled to a computing device, the computing device configured to output first switch signal data to the first control input to select which of the respective first throws is coupled to the first pole. The respective splitters can include respective splitter output ports coupled to respective second throws of respective second multi-throw switches, the respective splitters can include respective splitter control inputs coupled to the computing device, and the computing device can be configured to apply respective splitter signal data to the respective splitter control inputs to select which one or ones of the respective splitter output ports are coupled to the respective splitter input ports. The respective second multi-throw switches can include respective second poles coupled to respective qubits, and a second control input coupled to the computing device, and the computing device can be configured to apply second switch signal data to the second control input to select which of the respective second throws is coupled to the respective second poles. To couple a microwave signal from the microwave photon source to interact with a selected qubit of the respective qubits, the computing device can control the first multi-throw switch to couple the microwave signal to a selected input port of a selected splitter of the respective splitters, can control the selected splitter to couple the selected input port of the selected splitter to a selected output port of the selected splitter, in which the selected output port is coupled to a selected second throw of a selected second multi-throw switch of the respective second multi-throw switches, and in which the second pole of the selected second multi-throw switch is a selected second pole coupled to the selected qubit, and can control the selected second multi-throw switch to couple the selected second throw to the second pole of the of the selected second multi-throw switch.

At least one of the first switch, the respective splitters and the second switch can be deployed in a dilution refrigerator to operate at cryogenic temperatures.

The system further can include respective readout resonators associated with the respective qubits, in which the selected second throw can be a first selected second throw, respective first ends of the respective readout resonators can be coupled to respective second throws of the respective second multi-throw switches, respective second, opposite ends of the respective readout resonators can be coupled to a respective third throws of a third multi-throw switch, and the third multi-throw switch can include a third pole coupled to the computing device, respective third throws coupled to the respective second, opposite ends of the respective readout resonators, and a third control input coupled to the computing device. The computing device can be configured to output third switch signal data to the third control input to select which of the respective third throws can be coupled to the third pole, and the computing device can control the selected second multi-throw switch to couple a second selected second throw to the second pole of the of the selected second multi-throw switch, and to couple the second selected throw to a selected first end of a selected resonator associated with the selected qubit, and can control the third multi-throw switch to couple the selected second, opposite end of the selected resonator to the third pole for readout of the selected qubit by the computing device via the selected resonator.

The system further can include a digital signal multiplexer coupled to the computing device, and the computing device can be coupled, via the digital signal multiplexer, to the first control input of the first multi-throw switch, the respective splitter control inputs of the respective splitters, the respective second control inputs of the respective second multi-throw switches, and the third control input of the third multi-throw switch.

Readout of the selected qubit can include telemetry data to facilitate at least one of: real-time calibration or error detection by the computing device with respect to the selected qubit.

The third pole can be coupled to the computing device via an analog-to-digital controller.

The selected qubit corresponds to a quantum gate for execution of part of a quantum program.

The microwave signal can be a first microwave signal, wherein the selected qubit can be a first selected qubit that corresponds to a first quantum gate for execution of a first part of a quantum program in a first timeframe, and the computing device can further control the first multi-throw switch, the respective splitters, and the respective second multi-throw switches to couple a second microwave signal to a second selected qubit that corresponds to a second quantum gate for execution of a second part of the quantum program in a second timeframe.

The system further can include a digital signal multiplexer coupled to the computing device, and the computing device can be coupled, via the digital signal multiplexer, to the first control input of the first multi-throw switch, the respective splitter control inputs of the respective splitters, and the respective second control inputs of the respective second multi-throw switches.

The system further can include an arbitrary waveform generator coupled to the computing device via a digital-to-analog controller; the computing device can be configured to control the arbitrary waveform generator to generate a waveform, and the microwave signal can be based on the waveform.

The selected output port of the selected splitter can be a first selected output port, the selected second throw of the selected second multi-throw switch can be a first selected second throw, the selected second pole of the selected second multi-throw switch can be a first selected second pole, the selected qubit can be a first selected qubit. The computing device can control the selected splitter to couple the selected input port of the selected splitter to a second selected output port of the selected splitter in conjunction with the first selected output port being coupled to the selected input port, the second selected output port can be coupled to a second selected second throw of a second selected second multi-throw switch of the respective second multi-throw switches, and a second pole of the selected second multi-throw switch can be coupled to a second selected qubit. The computing device can control the second selected second multi-throw switch to couple the second selected second throw to the second pole of the second selected second multi-throw switch to couple the microwave signal to the second selected qubit in conjunction with the microwave signal being coupled to the first selected qubit.

The first selected qubit can correspond to a first quantum gate for execution of part of a quantum program in a clock cycle timeframe, and the second selected qubit can correspond to a second quantum gate for execution of the part of the quantum program in the clock cycle timeframe.

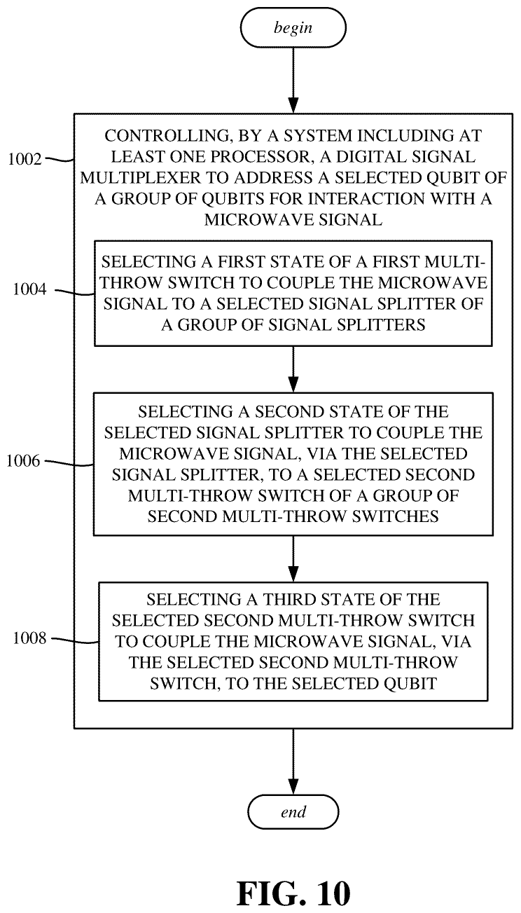

One or more example embodiments, implementations, and/or operations, such as corresponding to example operations of a method, can be represented in FIG. 10. Example operation 1002 represents controlling, by a system including at least one processor, a digital signal multiplexer to address a selected qubit of a group of qubits for interaction with a microwave signal, which can include example operations 1004, 1006 and 1008. Example operation 1004 represents selecting a first state of a first multi-throw switch to couple the microwave signal to a selected signal splitter of a group of signal splitters. Example operation 1006 represents selecting a second state of the selected signal splitter to couple the microwave signal, via the selected signal splitter, to a selected second multi-throw switch of a group of second multi-throw switches. Example operation 1008 represents selecting a third state of the selected second multi-throw switch to couple the microwave signal, via the selected second multi-throw switch, to the selected qubit.

Controlling the digital signal multiplexer further can include selecting a fourth state of a fourth multi-throw switch to couple a selected readout resonator associated with the selected qubit to the system for readout of state information corresponding to the selected qubit.

The microwave signal can be a first microwave signal having a first amplitude and a first phase, and further operations can include obtaining, by the system, the state information corresponding to the selected qubit, determining, by the system based on the state information, a second amplitude and a second phase of a second microwave signal, and controlling, by the system, the digital signal multiplexer to address the selected qubit for interaction with the second microwave signal. Controlling the digital signal multiplexer can include selecting the first state of the first multi-throw switch to couple the microwave signal to the selected signal splitter of the group of signal splitters, selecting the second state of the selected signal splitter to couple the microwave signal, via the selected signal splitter, to the selected second multi-throw switch of the group of second multi-throw switches, and selecting the third state of the selected second multi-throw switch to couple the second microwave signal, via the selected second multi-throw switch, to the selected qubit.

The microwave signal can be a first microwave signal, the selected qubit can be a first selected qubit, and further operations can include controlling, by the system, the digital signal multiplexer to address a second selected qubit of the group of qubits for interaction with a second microwave signal, which can include selecting a fourth state of the first multi-throw switch to couple the second microwave signal to a second selected signal splitter of the group of signal splitters, selecting a fifth state of the selected signal splitter to couple the microwave signal, via the second selected signal splitter, to a second selected second multi-throw switch of the group of second multi-throw switches, and selecting a sixth state of the second selected second multi-throw switch to couple the microwave signal, via the second selected second multi-throw switch, to the second selected qubit.

One or more example implementations can be embodied in a system. The system can include a switch array coupled to a microwave photon source and a first group of qubits. The switch array can include a first multi-throw switch coupled to the microwave photon source, a second group of signal splitters coupled to the first multi-throw switch, and a third group of second multi-throw switches coupled to the first group of signal splitters and to the first group of qubits. The system can include a computing device, and a multiplexer coupled to the computing device and to the switch array. The computing device can be configured to control the multiplexer to configure the switch array to couple a microwave signal from the microwave photon source to a selected qubit. The multiplexer can be controlled by the computing device to couple the multi-throw switch to a selected signal splitter of the second group of signal splitters, couple the selected signal splitter to a selected second multi-throw switch of the group of second multi-throw switches, and couple the selected second multi-throw switch to the selected qubit.

The system can include fourth multi-throw switch coupled to the multiplexer, coupled to a qubit readout line, and coupled to a fourth group of resonators respectively associated with the first group of qubits; the multiplexer can be controlled by the computing device to couple the fourth multi-throw switch to a selected resonator of the fourth group of resonators, the selected resonator being associated with the selected qubit to obtain quantum state information from the selected qubit for readout via the qubit readout line.

The selected second multi-throw switch can be a first selected second multi-throw switch, the selected qubit can be a first selected qubit, and the computing device can control the multiplexer to couple the selected signal splitter to a second selected second multi-throw switch of the group of second multi-throw switches, in conjunction with the selected signal splitter being coupled to the first selected second multi-throw switch, and controls the multiplexer to couple the second selected second multi-throw switch to the second selected qubit.

The selected second multi-throw switch can include phase change material.

As can be seen, the technology described herein integrates multi-throw switches and signal splitters at cryogenic temperatures into a qubit control system, reducing the need for separate control and readout lines for each qubit. This scalable approach consolidates microwave photon source routing, significantly decreasing the system's complexity. The system and architecture includes digital signal multiplexing for precise selection of qubits using address buses. This approach, along with the multi-throw switches and signal splitters, significantly reduce the number of physical control lines needed. Further, the system and architecture integrates a telemetry data collection and feedback system to allow for real-time calibration and error detection during qubit operations.

Note that current quantum computing systems rely on controlling the qubits directly via room-temperature electronics that is hardwired to the quantum device at cryogenic temperatures. Although superconducting qubits have made significant progress, reaching a stage where they can potentially be scaled to support fault-tolerant quantum computing, the integration of classical data conversion and processing hardware with quantum technology remains underdeveloped. To support large-scale quantum systems, classical control interfaces will operate at speeds that match the short coherence times of qubits, maintain low noise levels to avoid disrupting qubit operations, and be scalable in terms of physical resources. However, in existing quantum systems where each qubit is typically controlled and read out using its own dedicated microwave line, is not practical in quantum processors that scale to thousands or millions of qubits; the traditional wiring scheme is unsustainable in terms of space within the cryostat, while introducing considerable thermal load; the complexity of managing such large numbers of microwave lines while maintaining signal integrity and minimizing noise is also highly problematic.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system, comprising:
a first multi-throw switch comprising a first pole coupled to a microwave photon source, respective first throws coupled to respective splitter input ports of respective splitters, and a first control input coupled to a computing device, the computing device configured to output first switch signal data to the first control input to select which of the respective first throws is coupled to the first pole;
the respective splitters comprising respective splitter output ports coupled to respective second throws of respective second multi-throw switches, the respective splitters comprising respective splitter control inputs coupled to the computing device, the computing device configured to apply respective splitter signal data to the respective splitter control inputs to select which one or ones of the respective splitter output ports are coupled to the respective splitter input ports; and
the respective second multi-throw switches comprising respective second poles coupled to respective qubits, and a second control input coupled to the computing device, the computing device configured to apply second switch signal data to the second control input to select which of the respective second throws is coupled to the respective second poles,
wherein, to couple a microwave signal from the microwave photon source to interact with a selected qubit of the respective qubits, the computing device:
controls the first multi-throw switch to couple the microwave signal to a selected input port of a selected splitter of the respective splitters,
controls the selected splitter to couple the selected input port of the selected splitter to a selected output port of the selected splitter, wherein the selected output port is coupled to a selected second throw of a selected second multi-throw switch of the respective second multi-throw switches, and wherein the second pole of the selected second multi-throw switch is a selected second pole coupled to the selected qubit, and
controls the selected second multi-throw switch to couple the selected second throw to the second pole of the of the selected second multi-throw switch.

2. The system of claim 1, wherein the at least one of the first switch, the respective splitters and the second switch are deployed in a dilution refrigerator to operate at cryogenic temperatures.

3. The system of claim 1, further comprising respective readout resonators associated with the respective qubits,
wherein the selected second throw is a first selected second throw,
wherein respective first ends of the respective readout resonators are coupled to respective second throws of the respective second multi-throw switches,
wherein respective second, opposite ends of the respective readout resonators are coupled to a respective third throws of a third multi-throw switch,
wherein the third multi-throw switch comprises a third pole coupled to the computing device, respective third throws coupled to the respective second, opposite ends of the respective readout resonators, and a third control input coupled to the computing device, the computing device configured to output third switch signal data to the third control input to select which of the respective third throws is coupled to the third pole, and
wherein the computing device:
controls the selected second multi-throw switch to couple a second selected second throw to the second pole of the of the selected second multi-throw switch, and to couple the second selected throw to a selected first end of a selected resonator associated with the selected qubit, and
controls the third multi-throw switch to couple the selected second, opposite end of the selected resonator to the third pole for readout of the selected qubit by the computing device via the selected resonator.

4. The system of claim 3, further comprising a digital signal multiplexer coupled to the computing device, wherein the computing device is coupled, via the digital signal multiplexer, to the first control input of the first multi-throw switch, the respective splitter control inputs of the respective splitters, the respective second control inputs of the respective second multi-throw switches, and the third control input of the third multi-throw switch.

5. The system of claim 3, wherein the readout of the selected qubit comprises telemetry data to facilitate at least one of: real-time calibration or error detection by the computing device with respect to the selected qubit.

6. The system of claim 3, wherein the third pole is coupled to the computing device via an analog-to-digital controller.

7. The system of claim 1, wherein the selected qubit corresponds to a quantum gate for execution of part of a quantum program.

8. The system of claim 1, wherein the microwave signal is a first microwave signal, wherein the selected qubit is a first selected qubit that corresponds to a first quantum gate for execution of a first part of a quantum program in a first timeframe, and wherein the computing device further controls the first multi-throw switch, the respective splitters, and the respective second multi-throw switches to couple a second microwave signal to a second selected qubit that corresponds to a second quantum gate for execution of a second part of the quantum program in a second timeframe.

9. The system of claim 1, further comprising a digital signal multiplexer coupled to the computing device, wherein the computing device is coupled, via the digital signal multiplexer, to the first control input of the first multi-throw switch, the respective splitter control inputs of the respective splitters, and the respective second control inputs of the respective second multi-throw switches.

10. The system of claim 1, further comprising an arbitrary waveform generator coupled to the computing device via a digital-to-analog controller, the computing device configured to control the arbitrary waveform generator to generate a waveform, wherein the microwave signal is based on the waveform.

11. The system of claim 1, wherein the selected output port of the selected splitter is a first selected output port, wherein the selected second throw of the selected second multi-throw switch is a first selected second throw, wherein the selected second pole of the selected second multi-throw switch is a first selected second pole, wherein the selected qubit is a first selected qubit, and wherein the computing device:
controls the selected splitter to couple the selected input port of the selected splitter to a second selected output port of the selected splitter in conjunction with the first selected output port being coupled to the selected input port, wherein the second selected output port is coupled to a second selected second throw of a second selected second multi-throw switch of the respective second multi-throw switches, and wherein a second pole of the selected second multi-throw switch is coupled to a second selected qubit, and
controls the second selected second multi-throw switch to couple the second selected second throw to the second pole of the second selected second multi-throw switch to couple the microwave signal to the second selected qubit in conjunction with the microwave signal being coupled to the first selected qubit.

12. The system of claim 11, wherein the first selected qubit corresponds to a first quantum gate for execution of part of a quantum program in a clock cycle timeframe, and the second selected qubit corresponds to a second quantum gate for execution of the part of the quantum program in the clock cycle timeframe.

13. A method, comprising:
controlling, by a system comprising at least one processor, a digital signal multiplexer to address a selected qubit of a group of qubits for interaction with a microwave signal, comprising:
selecting a first state of a first multi-throw switch to couple the microwave signal to a selected signal splitter of a group of signal splitters;
selecting a second state of the selected signal splitter to couple the microwave signal, via the selected signal splitter, to a selected second multi-throw switch of a group of second multi-throw switches; and
selecting a third state of the selected second multi-throw switch to couple the microwave signal, via the selected second multi-throw switch, to the selected qubit.

14. The method of claim 13, wherein the controlling of the digital signal multiplexer further comprises selecting a fourth state of a fourth multi-throw switch to couple a selected readout resonator associated with the selected qubit to the system for readout of state information corresponding to the selected qubit.

15. The method of claim 14, wherein the microwave signal is a first microwave signal having a first amplitude and a first phase, and further comprising,
obtaining, by the system, the state information corresponding to the selected qubit;
determining, by the system based on the state information, a second amplitude and a second phase of a second microwave signal; and
controlling, by the system, the digital signal multiplexer to address the selected qubit for interaction with the second microwave signal, comprising:
selecting the first state of the first multi-throw switch to couple the microwave signal to the selected signal splitter of the group of signal splitters;
selecting the second state of the selected signal splitter to couple the microwave signal, via the selected signal splitter, to the selected second multi-throw switch of the group of second multi-throw switches; and
selecting the third state of the selected second multi-throw switch to couple the second microwave signal, via the selected second multi-throw switch, to the selected qubit.

16. The method of claim 13, wherein the microwave signal is a first microwave signal, wherein the selected qubit is a first selected qubit, and further comprising:
controlling, by the system, the digital signal multiplexer to address a second selected qubit of the group of qubits for interaction with a second microwave signal, comprising:
selecting a fourth state of the first multi-throw switch to couple the second microwave signal to a second selected signal splitter of the group of signal splitters;
selecting a fifth state of the selected signal splitter to couple the microwave signal, via the second selected signal splitter, to a second selected second multi-throw switch of the group of second multi-throw switches; and
selecting a sixth state of the second selected second multi-throw switch to couple the microwave signal, via the second selected second multi-throw switch, to the second selected qubit.

17. A system, comprising:
a switch array coupled to a microwave photon source and a first group of qubits, the switch array comprising:
a first multi-throw switch coupled to the microwave photon source;
a second group of signal splitters coupled to the first multi-throw switch; and
a third group of second multi-throw switches coupled to the first group of signal splitters and to the first group of qubits;
a computing device;
a multiplexer coupled to the computing device and to the switch array, the computing device configured to control the multiplexer to configure the switch array to couple a microwave signal from the microwave photon source to a selected qubit, the multiplexer controlled by the computing device to:
couple the multi-throw switch to a selected signal splitter of the second group of signal splitters,
couple the selected signal splitter to a selected second multi-throw switch of the group of second multi-throw switches, and
couple the selected second multi-throw switch to the selected qubit.

18. The system of claim 16, further comprising a fourth multi-throw switch coupled to the multiplexer, coupled to a qubit readout line, and coupled to a fourth group of resonators respectively associated with the first group of qubits, and wherein the multiplexer is controlled by the computing device to couple the fourth multi-throw switch to a selected resonator of the fourth group of resonators, the selected resonator being associated with the selected qubit to obtain quantum state information from the selected qubit for readout via the qubit readout line.

19. The system of claim 16, wherein the selected second multi-throw switch is a first selected second multi-throw switch, wherein the selected qubit is a first selected qubit, and wherein the computing device controls the multiplexer to couple the selected signal splitter to a second selected second multi-throw switch of the group of second multi-throw switches, in conjunction with the selected signal splitter being coupled to the first selected second multi-throw switch, and controls the multiplexer to couple the second selected second multi-throw switch to the second selected qubit.

20. The system of claim 16, wherein the selected second multi-throw switch comprises phase change material.
